(19) United States
(12) Patent Application Publication
(10) Pub. No.: US 2025/0266790 A1
(43) Pub. Date: Aug. 21, 2025

(54) Light Pulse Generator Method and Apparatus

(71) Applicant: Brightzone Power, Inc., Saint George, UT (US)

(72) Inventor: Christoph Karl La Due, Talent, OR (US)

(21) Appl. No.: 19/051,083

(22) Filed: Feb. 11, 2025

Related U.S. Application Data
(60) Provisional application No. 63/554,878, filed on Feb. 16, 2024.
(60) Provisional application No. 63/641,877, filed on May 2, 2024.

(51) Int. Cl. H02S 40/22; H02S 20/30; H02S 40/42

(52) U.S. Cl. CPC H02S 40/22; H02S 20/30; H02S 40/42

(57) ABSTRACT

A solar power generation system includes photovoltaic (PV) material onto which optically concentrated incident sunlight is transmitted from an optical concentrator during a first series of time intervals, thereby inducing and maintaining a state of continuous electron avalanche in the PV material, the PV material continually generating an electrical current that exceeds an electrical current generated by the PV material in the absence of electron avalanche. The system includes a control means that reduces a temperature of the PV material during a second series of time intervals that alternate with the first series of time intervals to maintain integrity of the PV material while electron avalanche is maintained in the PV material, electron avalanche breakdown is avoided in the PV material, and the PV material continues to generate the electrical current. An electrical load receives the electrical current continually generated by the PV material.

### CROSS REFERENCE TO RELATED DOCUMENTS

This application claims the benefit of U.S. Provisional Patent Application No. 63/554,878, filed Feb. 16, 2024, entitled “LIGHT PULSE PHOTOVOLTAIC SYSTEM (LPS) PERIODIC WAVE MECHANICS”, the disclosure of which is incorporated by reference herein in its entirety, and claims the benefit of U.S. Provisional Patent Application No. 63/641,877, filed May 2, 2024, entitled “LIGHT PULSE PHOTOVOLTAIC SYSTEM (LPS)”, the disclosure of which is incorporated by reference herein in its entirety. This application is related to US patent 10,673,377, issued Jun. 2, 2020, entitled “METHOD AND APPARATUS FOR ALTERNATING CIRCUIT SOLAR POWER GENERATION”.

### TECHNICAL FIELD

Photovoltaic solar power generation and, in particular, photovoltaic solar power generation that produces higher power output by maintaining a state of electron avalanche in the PV material.

### BACKGROUND

A goal of conventional operation of a photovoltaic cell is to generate a steady flow of electrical current. Static photovoltaic solar power generators are fundamentally inefficient. The static photovoltaic (PV) material in conventional flat solar panels is inadequately utilized. In other words, a flat solar panel deployed in prior art electrical power generation systems produces only a nominal amount of electrical energy from incident sunlight. The PV material is capable of producing much more electrical energy. Yet, the solar industry continues to focus on minor incremental improvements with new photovoltaic materials and combinations of static single-junction and multijunction materials with different bandgaps, substrate doping schemes, and other methods. What is needed is a system that dramatically increases solar power generation capability beyond present-day one-sun flat panel technology.

One way of improving the electrical generation performance of photovoltaic materials has been using various configurations of optical concentration systems joined with expensive multijunction materials and expensive refrigeration and or heat sink systems. The physics of optical concentration systems does not cause an increase in photon energy; instead, what changes with optical concentration is the number of photons incident in a unit area of photovoltaic material per unit of time, gathered from a larger primary optical surface such as microlens arrays and focused into a smaller optical output aperture through an optical waveguide such as a slab waveguide with coupling prisms, optical dimples, lenticular optics, and other optical means such as fiber optic multimode waveguides, larger scale molded light pipe arrays, that are coupled with microlenses, and or optical metalenses. This increased photon flux density leads to a higher intensity or power density, such as increased or enhanced photochemical reactions in the crystalline substrates that increase photocurrent levels in photovoltaic material. This is one of the reasons why electron avalanching occurs in photovoltaic material.

### BRIEF DESCRIPTION OF THE DRAWINGS

The features and advantages of the disclosed embodiments will become apparent from the details of the subject matter in which:

FIG. 1A illustrates a perspective view of an LPS 12 gon generator according to the disclosed embodiments.

FIG. 1B illustrates a side view of an LPS 12 gon generator according to the disclosed embodiments.

FIG. 2A illustrates the LPS 12 gon generator with planar micro-optics with the fiber optic and slab waveguide version according to the disclosed embodiments.

FIG. 2B illustrates aspects of the LPS 12 gon generator with planar micro-optics with the fiber optic and slab waveguide version according to the disclosed embodiments.

FIG. 2C illustrates further aspects of the LPS 12 gon generator with planar micro-optics with the fiber optic and slab waveguide version according to the disclosed embodiments.

FIG. 3 illustrates an LPS 32 generator according to the disclosed embodiments.

FIG. 4A illustrates aspects of an LPS generator system with partitioned photovoltaic material according to the disclosed embodiments.

FIG. 4B illustrates aspects of an LPS generator system with partitioned photovoltaic material according to the disclosed embodiments.

FIG. 4C illustrates aspects of an LPS generator system with partitioned photovoltaic material according to the disclosed embodiments.

FIG. 5 illustrates power output of a single facet-cluster of PV sections over a single revolution of the generator according to the disclosed embodiments.

### DETAILED DESCRIPTION

Light Pulse System (LPS) generator optomechanical technology, according to the disclosed embodiments, manages electron avalanching under controlled conditions, avoiding avalanche breakdown and subsequent damage to photovoltaic material while sustaining a high level of electricity generation in a cyclical and rhythmic pattern managed by electronics that govern electro-optical-mechanical functions with effective heat management.

Embodiments of the invention, also referred to herein as the Light Pulse System (LPS) Generator system, or simply, the LPS generator, is the first solar electrical power generation system that intentionally induces and controls a state of electron avalanching within the crystalline substrate of any photovoltaic (PV) material to yield greater power output than possible in prior art solar power generation systems that avoid the state of electron avalanche. In one embodiment, the state of electron avalanching is continuously maintained in the PV material while the system is operating and receiving concentrated incident light. This is accomplished through systemic periodic pulsing of the PV material with optically concentrated incident light. Periodically pulsing the PV material with optically concentrated incident light creates an on-and-off periodic interval where a burst of photons generates a burst of high-energy electron-hole pair carriers sufficient to induce a state of impact ionization-electron avalanche in the PV material. Each interval is followed by an interval in which no optically concentrated incident light reaches the PV material. This interval in which no optically concentrated incident light reaches the PV material provides time for reducing the temperature of the PV material, which is needed to maintain the state of electron avalanche in the material, while at the same time avoiding the occurrence of electron avalanche breakdown. Alternating between these two different intervals energizes the PV material to improve electrical energy production during systemically controlled impact ionization-electron avalanching, while avoiding electron avalanche breakdown, and reduces heat-induced phonon scattering and collisions with the lattice of the PV material that cause energy loss.

Phonons represent the collective vibrations of atoms in a crystal lattice. Phonons do not have mass or charge; they are simply disturbances in the regular arrangement of atoms in the lattice that comprises the crystalline substrate of the photovoltaic material. However, phonons play a crucial role in the material's heat conduction, thermal expansion, and other thermal properties. As temperature rises, the atoms in the photovoltaic material vibrate more vigorously, increasing the number and energy of phonons-lattice vibrations. These phonons then collide more frequently with the charge carriers-electrons and holes responsible for generating electricity. This increased scattering disrupts the flow of charge carriers, reducing their mobility and hindering their ability to reach the electrodes and contribute to the electrical current. The LPS generator system minimizes phonon scattering due to effective heat management, thereby avoiding, or minimizing energy loss, and yielding a higher level of electrical current than heretofore produced with PV material in prior art solar power generation systems.

The electrical energy levels produced according to the disclosed embodiments are novel and unprecedented in the history of the solar power industry. A solar cell photovoltaic material is a semiconductor designed like a diode; a photovoltaic material is considered a wide-area diode. Most other semiconductors used today utilize some form of pulsing mechanism. Diodes, transistors, and MOSFETs all operate with a periodic time-based function. Why not consider a photovoltaic cell that would operate much more efficiently when designed similarly to the other semiconductors? The next stage of advancing the efficiency of photovoltaic cells is through applying an external mechanism, managed by electronic controls, that creates a pulsating dynamic relationship with optically concentrated incident light and internal (crystalline lattice) and external (surface) photovoltaic material temperature control, which further establishes a method of controlling the rate of charge to photovoltaic material for increasing electrical power production, efficiency and sustained system operational integrity. Electron avalanching in photovoltaic material occurs in stages, as discussed below. When an LPS generator facet-cluster of photovoltaic material sections is energized with optically concentrated incident light during an interval, a high electric field is created as a starting condition. The high electric field accelerates charge carrier-electron-hole pairs to high energies. This field is established across the p-n junction in the photovoltaic material within the band gap boundary.

The high electric field accelerates the initial charge carriers, giving them kinetic energy. Once the charge carriers gain energy, they collide with atoms in the material's crystal lattice. The collision knocks out a bound electron from the valence band to the conductance band within the band gap of the photovoltaic material, creating an additional electron-hole pair. This is the impact ionization process. The newly freed electrons and original electrons are also accelerated by the electric field and cause further impact ionization events. This leads to a chain reaction rapidly multiplying the number of charge carriers-electron hole pairs, increasing the electron avalanching process. As the number of charge carriers multiplies, the charge density in the material increases. The high electric field is the driver; it provides the energy for impact ionization and sustains the electron avalanching process. Impact ionization is the mechanism, for it's the process that multiplies the charge carrier-electron hole pairs.

Electron avalanching is the outcome; it's the rapid increase in the number of charge carriers due to repeated impact events as a chain reaction. Charge density is a consequence, for it increases as the electron avalanche progresses and influences the electric field, and charge density is increased. This is the core cascading phenomenon. This cascading process is like an ever-increasing energetic spiral in the PV material. The spiral shape visually represents the multiplying effect of impact ionization. Each loop symbolizes a generation of charge carriers, and the spiral grows larger and larger as more carriers are created. The term “energetic” emphasizes the crucial role of the high electric field in accelerating the electrons and providing the energy for impact ionization. This is directly affected by the optically concentrated incident light level, for example, with a concentration ratio sufficient to induce and maintain a state of electron avalanche in the PV material, even for a period of time following the absence of light directed to the PV material, whether optically concentrated light or otherwise. The level of optically concentrated incident light may be, for example, two to one hundred times “one-Sun”, where “one-Sun” is a measure of solar irradiance of direct sunlight and can also be expressed in watts per meters squared (W/m²), where one Sun equals 1000 W/m² in many cases. The amount of optically concentrated light incident on the PV material depends on other factors, such as the time each facet cluster of PV material is subject to/under the optically concentrated light, the time interval for cooling the temperature of the PV material while it is not subject to incident light, etc. The point is to induce and maintain electron avalanche in the PV material, and avoid electron avalanche breakdown, by alternating between intervals where the PV material is subject to the optically concentrated light and followed by a period where the PV material is not subject to the optically concentrated light, allowing for cooling the temperature of the PV material, so that continuous energy is output by the PV material, even when the PV material is not subject to incident light.

The spiral is a conceptual model that can be imagined as gaining momentum and energy as it expands. This highlights the exponential growth of charge carriers in the avalanche process. The spiral expands outward, symbolizing the rapid multiplication of electrons and holes. Another way of visualizing the process is to imagine a bowling ball-hot carrier rolling down a lane-electric field. Without impact ionization, the bowling ball might hit some pins-lattice atoms, losing energy with each collision until it slows down and stops. With impact ionization, the bowling ball hits a pin and knocks it into multiple pins, creating additional electron-hole pairs. These pins also start moving down the lane, potentially hitting more pins and creating a cascading effect. When specific electromechanical and optomechanical characteristics are optimized for photovoltaic material efficiency, improved electrode conductor capacity, and efficient heat protection variables, there is no theoretical limit to what level of electrical power is generated with LPS generator-controlled impact ionization-electrical avalanching technology.

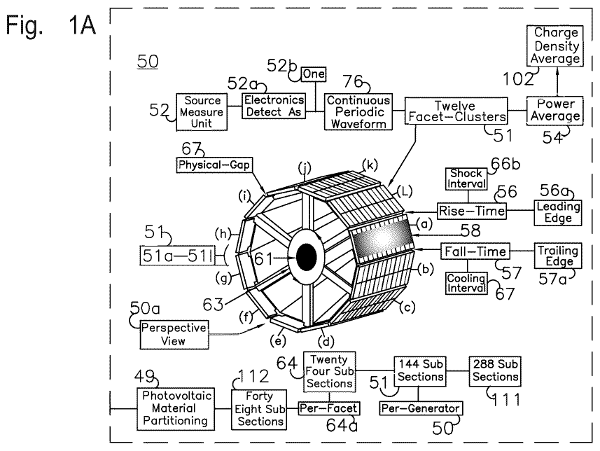

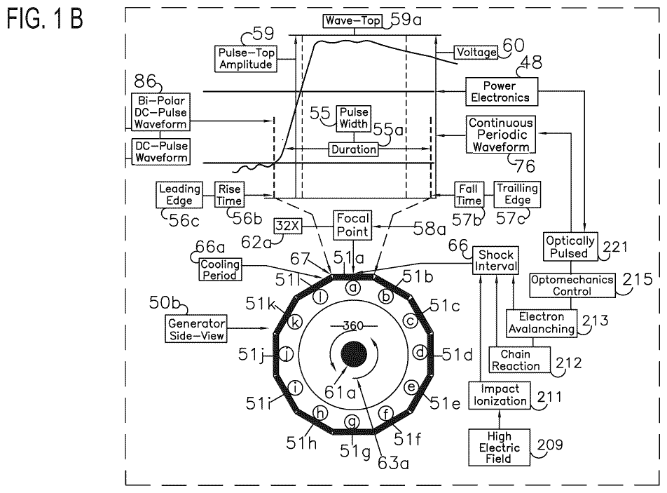

FIGS. 1A and 1B depict a solar power generator rotor design 50, or simply, a solar generator or generator 50, according to the disclosed embodiments, in two different views: 50a—perspective view; and 50b—side view. In this disclosed embodiment, the generator is mechanical in function and dodecagon (12 gon) in shape, comprised of twelve panels or facets, e.g., 3D printed carbon fiber composite panels or facets 51a to 51L, each configured with a cluster or a plurality of sections of photovoltaic (PV) material. According to one embodiment, the cluster of sections of PV material on a single facet are electrically coupled or wired together in series, so that the cluster produces a single power output value that is the combination of the power output of each section of PV material on the facet. This power output by the one cluster can be combined with the power output from one or more of the other clusters so that the generator produces continuous power output, not only for each facet-cluster, but for the generator as a whole, as described in further detail below. While the embodiment illustrated in FIGS. 1A and 1B has twelve panels or facets arranged in a dodecagon, it is appreciated an embodiment may have more or less panels or facets similarly arranged. For example, an embodiment may have six panels or facets concentrically arranged on a chassis around an axle in a hexagon, or eight or 24 panels or facets arranged in an octagon. Similarly, while the disclosed embodiments comprise panels or facets populated with a plurality of photovoltaic sections mounted on facet frames fabricated from 3D printed carbon fiber composites, other methods of manufacture and/or materials may be used in other embodiments.

The generator is attached via a frame or chassis to a common axle 61, 61a. In particular, each facet-cluster is attached via the frame or chassis to axle 61, 61a. A motor or energy source (not shown) is coupled to the axle to cause the axle to turn at a selected number of rotations or revolutions per minute (RPM), which, in turn, causes the generator to rotate the selected number of RPM. Alternatively, or additionally, the generator is powered by the solar energy that energizes the photovoltaic material. In one case, the generator rotates about the axle at 200 RPM, which produces 2400 continuous waveform pulses per minute (PPM), in an embodiment with 12 facets each comprising a cluster of PV material sections, wherein each facet produces a single pulse, or portion, of the continuous waveform each full rotation of the generator. As the generator rotates, a fixed focal point 58, 58a of optically concentrated incident light, focused by a lens (e.g., a Fresnel lens) and/or an optical concentrator, is projected on to each facet-cluster, one after the other as the PV sections rotate under the fixed focal point, contributing to the PV sections in the facet-cluster producing continuous electrical current. In this case, the focal point is an area with a dimension varying from 13 MM (in length) to 19 MM (in length) depending on the optical concentrator components in an embodiment. The total facet-cluster is 20 MM in length by 96 MM in width. Thus, if the width of the focal point is less than the width of the facet-cluster, the focal point will still cover the entire width of the facet-cluster as the generator rotates the facet-cluster under the focal point. Generating 2400 pulses per minute does not mean 2400 PPM produces 2400 complete electrical cycles like a full sinusoidal alternating current (AC) cycle that embodies a positive and negative waveform, for it takes two mirrored pulses to create a full AC electrical cycle. A core example states that a Bi-polar DC pulse comprises a positive pulse, followed by a negative pulse, which equates to a complete electrical cycle. At 2400 PPM, the LPS generator produces 1200 complete positive-negative electrical cycles, or 2400 pulses if the generator system is configured for DC pulse. This is important to understand when converting LPS electrical signals to other standard electrical waveform signaling. In another configuration, a continuous DC pulse signal is specified to enable electrical power applications requiring continuous direct current. In this case, 2400 electrical pulses are generated, contributing to a continued DC pulse signal.

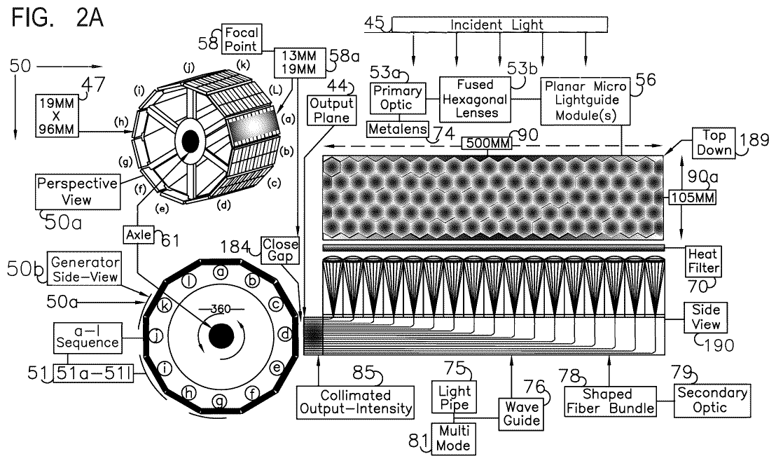

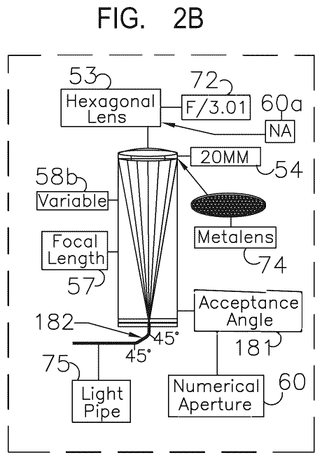

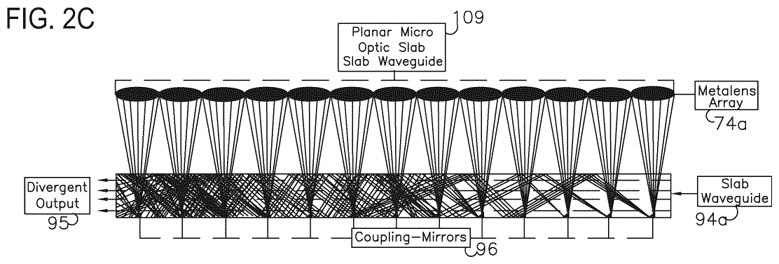

The physical dimensions of each LPS generator are completely arbitrary and only describe one of a plurality of proof of concept prototypal systems. Many types of photovoltaic materials have been tested, with many different form factors of geometric configurations for mechanical rotors. The incident light concentration ratio depends on the type of photovoltaic material utilized, from single junction to multijunction, organic solar cells, perovskite, thin film, graphene, and the like. A concentration ratio of 32×, 62a, is used in one case. The 12-gon generator rotates, e.g., in a counterclockwise direction 63, 63a, and the concentrated incident light energizes each facet cluster in turn due to the physical rotating movement of the generator. The focal point may vary in width from 13 MM to 19 MM 58, 58a, because of the design constraints imposed by the limitations of a 500 MM long by 105 MM wide linear Fresnel lens. In FIGS. 2A and 2B, however, with the application of planar optical concentrators, a focal point of 19 MM by 96 MM 47 illuminates the entire facet-cluster 51, 51-51L as the generator rotates in an (a) to (l) sequence. The focal point 58, at the focal plane 44 illuminates each facet-cluster 51a-51L in a timed sequence 1-12 as the 12-gon generator rotates.

In FIGS. 1A and 1B, the photovoltaic generator illustrated in perspective view 50a and side view 50b is comprised of a plurality of facet-clusters of sections of PV material, for example, 12 facet-clusters 51a through 51L, that rotate and pass by, or under, the concentrated incident light focal point in a cyclical manner. A continuous power level is maintained during the interval between facet clusters because each facet cluster sustains its own continuous power well after rotating out of the concentrated incident light focal point. In fact, a continuous, if diminishing, power level is maintained by each facet cluster until it rotates back under the concentrated incident light focal point, at which point, the power level output by the facet-cluster increases. An electrical rise time of the photovoltaic material occurs as a physical phenomenon when incident light hits the material, causing it to absorb photons and release electrons at a higher energy state. The main photovoltaic effect is a quantum state that rectifies light into electric current. In more detail, the photovoltaic effect is a consequence of three main quantum mechanical processes: (a) absorption of photons, (b) generation of electron-hole pairs, and (c) separation and collection of electron-hole pairs as usable electrical current. More concentrated light, in one embodiment, 32× optical concentration ratio, optimizes these quantum effects, which yields an increase of electrons and generates much more electrical current to an electrical load point. In some cases, the optical concentration ratio may be increased or decreased.

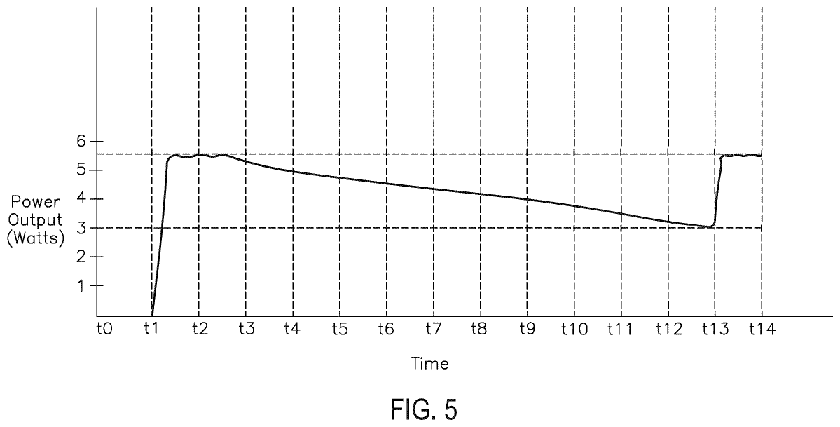

Depicted in FIG. 1A and 1B, simultaneously, one pulse of a continuous periodic waveform 76, as depicted graphically as a replica of a generated image on the screen of an oscilloscope or comma-separated value (CSV) that is a universal data format used to measure electrically generated power with many types of source measure units (SMU). A continuous periodic waveform 76 produced by a rotating solar power generator comprises a continuous electrical power signal. Typically, generated waveforms are sinusoidal. In this case, the LPS electrical waveform is a sawtooth waveform 76 without sinusoidal characteristics, as depicted and discussed further below with reference to FIG. 5. The waveform may be manipulated by facet output electrical circuitry depending on how it is configured to output the waveform to load. The generated signal from each facet cluster may be combined in a common circuit topology, according to one embodiment. As shown in FIG. 1A, mechanical rotation of a facet cluster under the focal point produces electrical current generation, which begins at rise time 56 at the waveform's leading edge 56b. As the facet-cluster 51a rotates counterclockwise 63, 63a, the pulse waveform quickly increases in amplitude as denoted by the pulse top amplitude 59 and voltage 60, which equates to the wave-top 59a in this case. The wave-top width 55 is sustained for a duration of 55a based on the time frame that the facet-cluster is under the focal point. In one case, a 12-gon generator rotates at 200 RPM, producing 2400 PPM.

In FIGS. 1B, 2A, 2B and 2C, as the facet-cluster 51a moves past the focal point 58, 58a, the physical and electrical fall time 57, 57b coincides with the trailing edge 57a, 57c due to the rotation of the generator at 200 RPM and producing 2400 PPM, ensuring that electrical energy continues to be generated when each facet-cluster 51a to 51f moves in and out of the concentrated light focal point 58, 13 MM-19 MM in height 58a, generating continuous electrical energy from each facet-cluster, as the generator rotates 360° degrees.

In the first instance, the facet-cluster 51a rotates into the optically concentrated light 58a, initiating shock interval 66, 66b. The optically concentrated incident light, with condensed photonic energy, creates a high electric field 209, initiating impact ionization 211 in the PV material of the facet-cluster during the interval, which is a phenomenon when an energetic charge carrier collides with an atom in the photovoltaic material crystal lattice, transferring enough energy to excite a bound electron into the conduction band, leaving behind a hole in the valence band. An electron-hole pair gains sufficient energy to liberate a bound electron from the valence band to the conduction band, creating another electron-hole pair. This process creates a high electric field 209, which leads to impact ionization 211, which initiates a chain reaction 212 known as electron avalanching 213, and continues to accelerate the initial energetic charge carrier to a higher energy state, accelerating electrons and causing ionization that further creates a plasma field within the photovoltaic material crystal lattice substrate during the interval 66. Thus, the PV material in the facet-cluster generates an electrically conductive plasma. The physical gap 67 between each of the 12 facet clusters in material space is a distinct optoelectrical boundary that creates a leading-edge 56a rise time 56 between each facet cluster 51a to 51f.

In FIGS. 1B, 2A, 2B and 2C, examining each facet cluster of the generator rotor side view, for example, 50b, the facet cluster 51a is fully charged. As this facet-cluster rotates out of the focal point from the optically concentrated incident sunlight at 200 RPM, the process of impact ionization and electron avalanching continues during a full 360-degree rotation vector. Electrical energy does dissipate to a level commensurate with the intensity of impact ionization and electron avalanching of each facet cluster 51a to 51L which is governed by the available incident sunlight. Each facet cluster continues to generate electrical energy in and out of the optical focal point, thus creating a continuous waveform 76 signal in 360° degrees of continuous electromechanical rotation. This waveform is enabled without needing an inverter and can produce alternating current (AC) waveforms and standard sinewaves with the onboard power electronics 48. This waveform can be converted to a standard alternating current (AC) squarewave, sinewave, etc. The continuous waveform continues as long as an electromechanical generator source continues to function in the presence of incident sunlight. In this case, the 12-gon generator continues to rotate due to the reception of concentrated incident light; the generated waveform remains constant. Generated electrical power only fluctuates due to the instant atmospheric condition that affects the full spectrum incident sunlight level received by an LPS generator.

As depicted in FIGS. 2A and 2B, there is an example of an LPS 12-gon generator 50 in perspective view 50a and side view 50b, mated together with a planar light guide module, comprised of a primary optic array 53a, that is populated with a lens or lens array, for example, a fused hexagonal plano-convex lens array 53b. A hexagonal plano-convex lens is a lens with one flat surface and one convex surface that is shaped like a hexagon. In this case, a hexagonal lens 53b can be 5 MM to 20 MM plus in diameter as depicted at 54. Hexagonal lenses 53b comprise the primary optic, which gathers incident light vertically. Each microlens focuses and couples into and out of each optical fiber and a larger format light guide. In FIG. 2, and FIG. 2B, a hexagonal lens 53b has a f-number of f/3.01, 72 in one example. An F/3.01 hexagonal lens is a lens with a maximum aperture of f/3.01. The aperture is the opening in a lens that controls the amount of light passing through. The f-number is a ratio that describes the size of the aperture. It's calculated by dividing the lens's focal length 57 by the diameter of the aperture. A smaller f-number means a wider aperture, and a larger f-number means a narrower aperture. Additional optical elements include numerical aperture (NA) 60. NA is a dimensionless number that characterizes the range of angles over which an optical system, like a lens, fiber optic, or light pipe 75, can accept or emit light. The acceptance angle 181 is the maximum angle within that cone at which the light can strike the fiber's core and light pipe core and still be guided through it via total internal reflection.

This gathered light propagates through the core of an optical fiber or light pipe with a process called total internal reflection (TIR) within the optical structure of an accumulative multimode 81, light pipe 75 fiber optic waveguide 74. A more efficient and versatile alternative to hexagonal microlenses is optical metalenses 74, 74a as depicted in FIGS. 2B and 2C. Metalens are typically thin and lightweight. Metalenses can be much thinner and lighter than traditional lenses. Metalens comprise an arrangement of meta-atoms that create nanostructures such as nanorods, nanofins, rectangles, triangles, and the like. These nanostructures can be twisted, titled, and arrayed to manage light phase profiles and the like. Metalenses can be designed to perform various optical functions, including focusing, beam shaping, light bending, and polarization control. Metalens nanostructures can array in concentric rings, grids, and spirals to perform several useful functions, such as optical tracking of the sun as it traverses across the azimuth from horizon to horizon. Metalenses can be cheaper to manufacture than traditional lenses, especially as nanofabrication techniques advance. Metalenses can be designed to have specific focal lengths and variable focal lengths. In this case, like the hexagonal lens 53b a metalens can be 5 MM to 20 MM 54 plus in diameter.

In FIGS. 2A, 2B and 2C, hexagonal plano-convex lenses and or metalenses 74 capture and direct incident light 45, which is collimated at 85 and focused on the optical output plane 44 to the focal plane. The focal plane is perpendicular to the optical axis that passes through the focal point 58, with a physical dimension that can range from 13 MM to 19 MM 58a, where focused light gathers and converges with equal collimation on each facet-cluster 51 as the generator rotates on the axle 61 from 51a to 51L. The distance between the output plane of the shaped fiber light guide bundle 78 that comprises the secondary optics 79 is a close gap 184 that allows the LPS generator frame angles to pass by the optical output plane surface while enabling minimal light scattering so that each facet-cluster absorbs as much optically concentrated light as possible. Metalenses 74, 74a enable accurate gradient index configurations (GRIN) by tuning each nanostructure during manufacture. Gradient indexing in optics enables shifting refractive index, and shifting phase from the surface of a metalens optic to bend light from one direction and point the same light to the collimated 85 output plane 44. Metalenses and gradient lenses, manipulate light by precisely controlling the phase of the light waves. They do this by introducing tiny structures or variations in material properties that cause different parts of the light wave to experience different phase shifts. In this way, gathered light incident on the surface is projected perpendicularly to the surface of each LPS generator facet-cluster through the shaped fiber bundle 78 that acts as the secondary optic 79.

Each facet-cluster is 20 MM in length by 96 MM-105 MM in width, and the shaped fiber light guide bundle is also 13 MM-20 MM in length by 96 MM-105 MM in width. The object is to ensure that all output incident light comprised of photons energizes the rotating LPS generator. In FIG. 2C, another variation of the planar micro-optic waveguide 94, 94a that utilizes a micro metalens array 74, 74a. The only significant difference is that instead of utilizing optical fibers and light pipe arrays, the planar waveguide comprises polymethyl methacrylate (PMMA) acrylic optical plastics. Set within the bottom of the slab waveguide is an array of coupling mirrors 96 that can be etched, micro-milled, formed with SU-8 plastics, and the like. Light projected from each microlens is bent at an angle that sends the light to the divergent output 95. As shown in FIG. 2A, a heat filter 70 can be applied. Heat filters and antireflection compounds can be applied by spraying as a coating during manufacturing to ensure the highest optical efficiency possible.

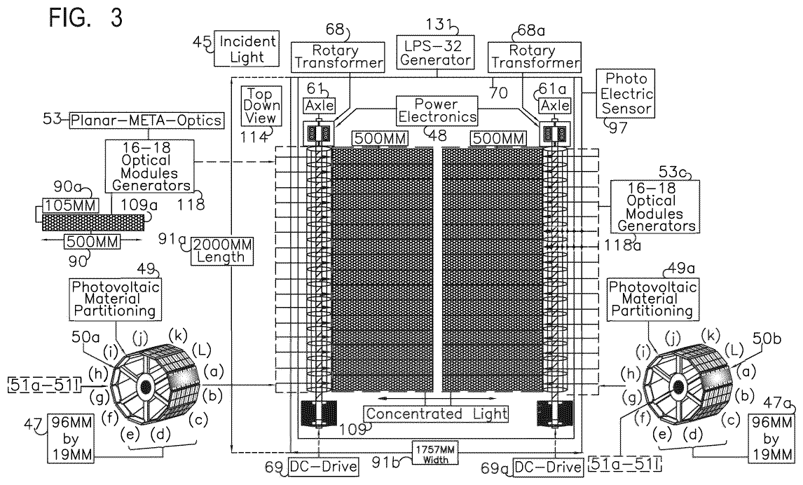

FIG. 3 depicts a multi-generator commercial flat panel, e.g., a 32-generator commercial flat panel. All the detailed specifications of the single LPS generator 50, 50a depicted in FIG. 1A, FIG. 1B, and FIGS. 2A-2C, are the exact specifications and configurations of the 32 generators that are disclosed in FIG. 3, according to one disclosed embodiment. In FIG. 3, the LPS 32+ generator system utilizes two magnetic DC drives, 69 and 69a, comprising magnetic coils with no surface wear points. Once started, these drives consume very little electrical energy because there is nominal rotational resistance once the threshold of 200 RPM is sustained. These DC drive bearings ride on a permanent magnetic field. The axle assembly system 61, 61a utilizes magnetic bearings on each end of the 16-generator array assembly 118, 118a. The 32 LPS system is designed as a commercial solar panel, with a length of 2000 MM 91a and a width of 1757 MM 91b. Tests in 32× concentrated sunlight showed that each generator 50, as shown in FIGS. 1A and 1B has produced average power equal to 100% efficiency under I/V curve testing with a source measure unit (SMU). This same generator design array, a total of 16 generators on each of two common axles 61 and 61a for a total of 32 generators, produces 2000 watts or more of electrical power under the I/V curve and/or electrical load points. A standard commercial panel with approximately the same physical dimensions produces only 400-600 watts with ideal atmospheric conditions on a good day. This 32-generator panel utilizes planar micro-optic waveguide modules 56, 56a, 56b.

In FIG. 3, each optical module is 500 MM 90 in length by 105 MM 90a in width. The LPS-32 system can also utilize another form of micro-optic slab concentrator that combines an array of microlenses and metalenses with a multimode slab waveguide 94a, as shown in FIGS. 2A-2C. In FIG. 3, this generator example uses a DC servo motor 69, 69a, to rotate LPS generator on array 118, 118a on common axles. FIG. 3 depicts an LPS generator array comprised of 32 generators. Each one is the same configuration as generator 50 depicted in FIGS. 1A and 1B. The generator also uses a 24-channel rotary transformer to transfer positive and negative electrical energy from all 12 facets from the rotating medium (rotor) to a stator (stationary) to associated electronics that convert the originating electrical pulse wave to any type of desired waveform such as standard electrical sinewave. As depicted in FIG. 3, 24-channel rotary transformers 68 and 68a are more efficient than electrical slip rings. Rotary transformers do not have any friction points. Like most electrical transformers, a rotary transformer comprises a primary and secondary coil. All transformers use electromagnetic induction to transfer electrical energy between coils or circuits through a magnetic field. The disclosed embodiments use a 1:1 equal transfer between the primary coil-rotor that is physically and electrically connected to the 24-channel output of the 16-18 LPS generator arrays depicted on each side of the 32 generators. Electromagnetic induction transfers the electrical energy generated from each 16-generator array to the secondary coil-stator (stationary). The 32 generator panels power electronics 48 receive a continuous waveform 76, as shown in FIGS. 1A and 1B, which convert this source signal to standard AC waveforms and other signals to selected electrical load points. Power Electronics 48 control the DC drive that rotates the generator 50b. During rotation, optically pulsed 221 incident light at the focal point 58a, generates continuous periodic waveforms 76, and optomechanical control 215 that is managed with the LPS generator power electronics 48. In FIG. 3, each LPS generator 50a, 50b comprises facet-clusters and each facet-cluster is constructed of multiple sections of photovoltaic material partitioning 49, 49a.

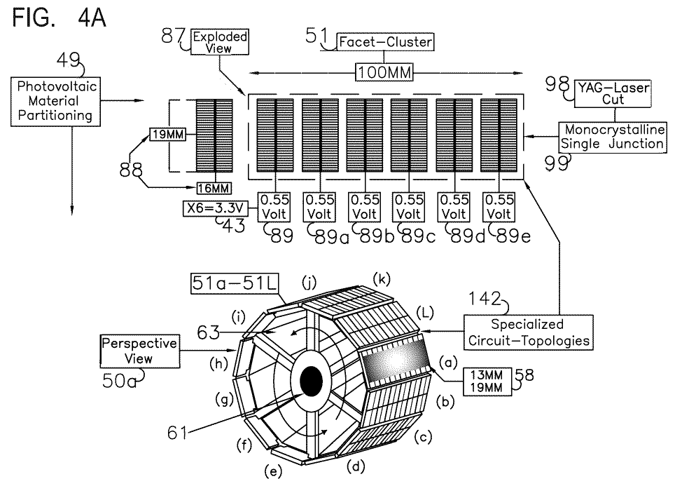

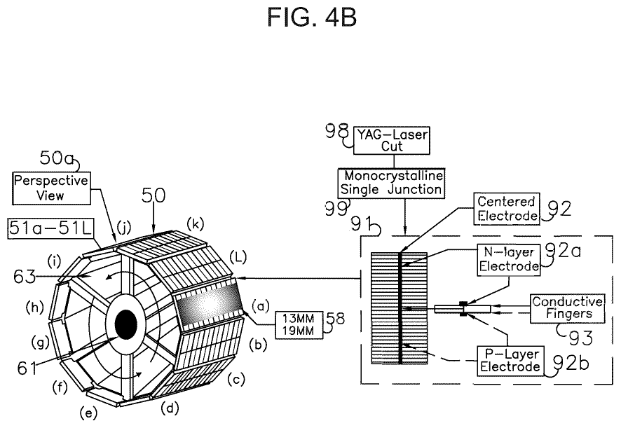

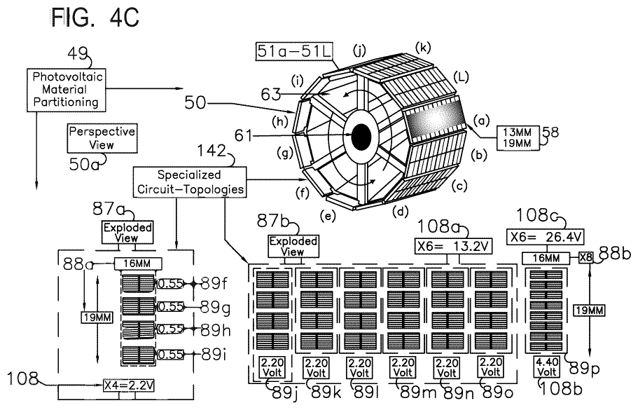

As depicted in FIGS. 4A, 4B, and 4C, photovoltaic partitioning 49 is illustratively shown in multiple cases. The LPS generator shown in perspective view 50a, has 12 facet-clusters 51a to 51L. Facet-cluster 51 shows an exploded view 87 of approximately 100 MM of partitioned monocrystalline single junction 99 photovoltaic material. An entire 6″×6″ wafer is YAG-laser cut monocrystalline single junction solar cell 98 into multiple sections. In FIG. 4B additional modifications include adding thicker center electrode 92 on the top N-layer electrode 92a, and the bottom P-layer electrode 92b. The conductive fingers 93 are also better connected to center electrodes 92 on both N-layer electrode 92a, and P-layer electrode 92b with military-grade solder. In FIG. 4A, the exploded view 87 shows six 19 MM by 16 MM photovoltaic sections 88. Each section 89 to 89e generates 0.55 volts, for a total of 3.3 volts 43. In FIG. 4C, exploded view 87a illustrates photovoltaic partitioning where each 6″×6″ monocrystalline wafer is YAG-laser cut into even smaller sections. Note four subsections 89f, 89g, 89h, and 89i. Each subsection generates 0.55 volts for a total of 2.2 volts 108. The total dimensional space is 19 MM by 16 MM 88a. The exploded view 87b depicts four sections 89j, 89k, 89l, 89m, 89n, and 89o, each being YAG-laser cut into four subsections. All 24 subsections equate to 13.2 v per facet-cluster 108a. One 12-gon generator has 144 subsections. Total voltage potential is 79.2 volts. In still another configuration, one facet-cluster 89p section is YAG-Laser cut into eight subsections, which equate to 4.4 volt 108b, x6=26.4 volt 108c equals 158.4 volts for all 12 facets clusters equals 316 volts for the complete LPS 12-gon generator in this case. Each LPS generator has unique and specialized circuit topological patterns 142 designed for maximum electrical power generation and distribution.

FIG. 5 illustrates graphically the continuous power output of a single facet-cluster, e.g., facet-cluster 51a in FIG. 1B, as it completes a 360-degree rotation in the generator according to the disclosed embodiments. At time t0, presume the generator is just starting and facet-cluster 51a is positioned in the 1 o'clock position. The generator rotates the chassis in a counterclockwise position, so that facet-cluster 51a, given it is mounted to the chassis, also rotates during time t0 to t1, so that at time t1, facet 51a is entering the 12 o'clock position under the focal point 58a. As the generator continues to rotate in a counterclockwise position, facet-cluster 51a passes directly under the focal point (at the 12 o'clock position) and therefore receives optically concentrated incident light. The optically concentrated light induces electron avalanche in PV material sections in the facet-cluster 51a, resulting in the facet-cluster 51a producing power output of approximately 5.6 watts during time t1-t2, while the facet-cluster is receiving the optically concentrated incident sunlight. This power output is much greater than the power output of the facet-cluster in a static/stationary flat panel display in a one-sun environment, which would only achieve power output of about 3 watts for the same unit area of PV material.

During time t2-t3, the facet-cluster 51a rotates out from under the focal point and is positioned in the 11 o'clock position. Even though the facet-cluster 51a is no longer receiving incident light, the facet-cluster 51a continues to output power, at a level only slightly diminished from the level output during time t1-t2, because the PV material continues to be in a state of electron avalanche and therefore continuing to produce power. In contrast, the facet-cluster in a static/stationary flat panel display in a one-sun environment would not continue to output power, since no sunlight is incident on the facet-cluster and no electron avalanching occurs.

During time t1-t2, the PV material in facet-cluster 51a nominally heats up when receiving the optically concentrated incident light. However, during time t2-t3, the facet-cluster 51a cools down immediately 66a since it is no longer receiving incident light 45. This cooling continues during intervals t3-t4, t4-t5 and so on, until the facet-cluster 51a rotates all the way around and back under the focal point 58a at interval t13-t14 in this disclosed embodiment. This cooling of the PV material is important to avoid electron avalanche breakdown. Also, during the period of time that spans time intervals t2-t13, the facet-cluster 51a continues to output power, albeit at a slightly diminished level, reaching about 3 watts of output power by the time the facet-cluster 51a is reenergized at interval t13-14, at which point the above-described process repeats. In this manner, a single facet-cluster of PV material produces continuous output power.

Additionally, the other facet-clusters 51b-51L produce the same power output waveform or curve as facet-cluster 51a, time shifted according to their respective location in the generator. So, for example, facet-cluster 51b is producing 5.6 watts of output power while under focal point 58a at time interval t2-t3, while facet-cluster 51a is in the 11 o'clock position, facet-cluster 51c is generating peak power output while under focal point 58a at time interval t3-t4, while facet-cluster 51a is in the 10 o'clock position and facet-cluster 51b is in the 11 o'clock position. Thus, each facet-cluster generates continuous power output, and the combination of facet-clusters generates a continuous power output that is the sum of the instantaneous power output of each facet-cluster. While the described embodiment contemplates 12 facet-clusters, it is appreciated that fewer or more facet-clusters may be used in an embodiment. Thus, more generally, if the full rotation time for the generator is T, and there are n facet-clusters, each facet cluster receives optically concentrated light under the focal point for a period of time equal to 1/n(T), and cools down for a period of time equal to (n−1)/n(T), so as to maintain electron avalanche in the PV material in the facet-cluster, which in turn yields greater power output compared to flat panel systems under one-sun conditions, and at the same time avoids electron avalanche breakdown that otherwise occurs due to sustained overheating of the PV material.

LIGHT PULSE GENERATOR METHOD AND APPARATUS

1. A solar power generator system, comprising:
a photovoltaic (PV) material onto which optically concentrated incident sunlight is transmitted from the optical concentrator during a first series of time intervals, thereby inducing and maintaining a state of continuous electron avalanche in the PV material, the PV material continually generating an electrical current that exceeds an electrical current generated by the PV material in the absence of a state of continuous electron avalanche in the PV material;
a control means that reduces a temperature of the PV material during a second series of time intervals that alternate with the first series of time intervals to maintain integrity of the PV material while the state of continuous electron avalanche is maintained in the PV material, a state of electron avalanche breakdown is avoided in the PV material, and the PV material continues to generate the electrical current; and
an electrical load to receive the electrical current continually generated by the PV material.

2. The solar power generation system of claim 1, further comprising:
a lens through which passes incident sunlight; and
an optical concentrator having an input aperture and an output aperture, the input aperture to receive the incident sunlight that passes through the lens, the optical concentrator to optically concentrate the incident sunlight received via the input aperture, the output aperture to transmit the optically concentrated sunlight.

3. A solar power generator, comprising:
a lens, positioned in a two-dimensional plane, through which to receive radiant energy from the sun;
an optical concentrator having an input aperture and an output aperture, the input aperture to receive the radiant energy from the sun that passes through the lens, the optical concentrator to optically concentrate the radiant energy received via the input aperture, the output aperture to transmit the optically concentrated radiant energy;
a drive shaft having a longitudinal axis positioned near and substantially parallel to the two-dimensional geometric plane of the lens and the optical concentrator;
a motor coupled to one end of the drive shaft to rotate the drive shaft about the longitudinal axis at a constant speed; and
a plurality of solar modules coupled to the drive shaft, each comprising photovoltaic material, and each forming one of a corresponding plurality of planar facets in coaxial alignment with respect to the drive shaft, such that as the motor rotates the drive shaft at a constant speed, each of the plurality of solar modules repeatedly rotates by the output aperture of the optical concentrator for a respective first time period, receives the optically concentrated radiant energy during the respective first time period, thereby inducing and maintaining a state of continuous electron avalanche in the PV material and continually generating an electrical current that exceeds an electrical current generated by the solar module in the absence of a state of continuous electron avalanche in the PV material, each of the solar modules rotating outside the output aperture of the optical concentrator during a respective second time period during which a temperature of the PV material reduces to maintain integrity of the PV material while the state of continuous electron avalanche is maintained in the PV material, a state of electron avalanche breakdown is avoided in the PV material, and the solar module continues to generate the electrical current.
